(19) United States
(12) Patent Application Publication
(10) Pub. No.: US 2025/0192769 A1
(43) Pub. Date: Jun. 12, 2025

(54) ADAPTIVE IGBT ACTIVE DRIVE CIRCUIT SUITABLE FOR POWER ELECTRONIC ENERGY EQUIPMENT

(71) Applicant: Hefei Institutes of Physical Science, CAS, Hefei City (CN)

(72) Inventors: Liansheng HUANG, Hefei City (CN); Jiamin ZHOU, Hefei City (CN); Sheng DOU, Hefei City (CN); Xiaojiao CHEN, Hefei City (CN); Shiying HE, Hefei City (CN); Xiuqing ZHANG, Hefei City (CN); Zejing WANG, Hefei City (CN); Lingpeng LI, Hefei City (CN)

(21) Appl. No.: 18/922,652

(22) Filed: Oct. 22, 2024

(30) Foreign Application Priority Data
Dec. 11, 2023 (CN) 202311688026.5

(51) Int. Cl. H03K 17/16

(52) U.S. Cl. CPC H03K 17/168

(57) ABSTRACT

An adaptive IGBT active drive circuit is divided into two parts: a gate drive circuit, and a feedback circuit. The gate drive circuit includes a totem pole unit, and multi-level resistance switching is achieved by using a totem pole parallel structure. The feedback circuit includes a comparison unit, and a logic unit. The comparison unit includes divided resistors, sampling resistors, and a comparator. Internal currents, after passing through the sampling resistor, are compared with current comparison thresholds of complementary transistors to output a digital signal to participate in control of the totem pole. The logic unit is responsible for logically combining a PWM signal and a signal output by the comparison unit to obtain a driving signal of the totem pole.

### RELATED APPLICATION

This patent application claims the benefit and priority of Chinese Patent Application No. 2023116880265 filed with the China National Intellectual Property Administration on Dec. 11, 2023, the disclosure of which is incorporated by reference herein in its entirety as part of the present application.

### TECHNICAL FIELD

The present disclosure relates to the field of switching power supply, and in particular to an adaptive IGBT active drive circuit suitable for power electronic energy equipment.

### BACKGROUND

Insulated Gate Bipolar Transistor (IGBT), as the most widely used semiconductor power device in the field of power electronic devices, has been widely used in medium-high power circuit conversion systems and related industries. The IGBT device, due to its high switching frequency, mature related technology, and stable operation performance in high voltage and high current environment, can be well applied in active switching control process, passive short-circuit shutdown and other conditions, which eliminates the demand of shutting down the whole electrical network during system operation, thereby improving the reliability of system operation greatly. Thus, the IGBT is widely used in various high-power converter system.

Different from the usual small and medium-sized power electronic conversion apparatuses, the high-power power electronic conversion equipment has high line parameter setting, and large system package size, which causes the stability of the main circuit loop to be greatly affected by line parasitic capacitance and parasitic inductance. Bus voltage and load current of the high-power power electronic equipment are generally high, and thus the abrupt change of voltage or current signal will cause overshoot and over-stress on device, due to the existence of stray inductance when the system operates at a high switching frequency, which will lead to IGBT breakdown in serious cases. Therefore, the high efficiency, low loss and high stability of IGBT are related to the operation stability of the power electronic device. In the process of IGBT switching, the turn-off time is short, and due to the existence of parasitic inductance, when the collector current drops, the generated di/dt value is high, which results in high induced voltage across the inductor. A voltage peak may appear on IGBT after the induced voltage and the bus voltage are superimposed. During switching of on/off state of the IGBT, due to the existence of complementary switch diodes, high current overshoot will occur across the IGBT, which will seriously lead to faults such as cross talk and mistaken turn-on of a main circuit, thereby resulting in a serious threat to the normal operation of the device. Because the IGBT operates in high-frequency and high-power situation, the switching loss is high, but the reduction of the switching loss means that the turn-off overvoltage or the turn-on overcurrent increases, which is unfavorable to the device. Such a situation is more obvious in the application of high-power IGBT modules. Moreover, because the performance of the driver, such as driving speed, is the direct factor that affects IGBT operating performance, improving IGBT device reliability and driver optimization is an important research direction for IGBT technology development. As one of the key technologies in the application field of IGBT, IGBT active driving technology plays a vital role in the reliable operation of high-power power electronic conversion devices, which directly affects the operating efficiency, safety and reliability of the system. For different voltage and current levels and different topologies, it is also of a great research significance to improve the applicability of the driver.

Traditional driving methods cannot optimize both voltage and current oscillation and switching loss. Compared with the traditional driving methods, active gate driving can dynamically change equivalent driving resistance, driving voltage or driving current by actively adjusting the gate driving signal at some phases in the switching process, so as to achieve the effective balance among the switching speed, the switching loss and current/voltage overshoot, thereby improving the controllability of the drive circuit in the switching process.

### SUMMARY

An adaptive IGBT active drive circuit is divided into two parts: a gate drive circuit, and a feedback circuit. The gate drive circuit includes a totem pole unit, and multi-level resistance switching is achieved by using a totem pole parallel structure. The feedback circuit includes a comparison unit, and a logic unit. The comparison unit includes divided resistors, sampling resistors, and a comparator. Internal currents, after passing through the sampling resistor, are compared with current comparison thresholds of complementary transistors to output a digital signal to participate in control of the totem pole. The logic unit is responsible for logically combining a PWM signal and a signal output by the comparison unit to obtain a driving signal of the totem pole.

### DESCRIPTION OF THE DRAWINGS

FIG. 1 is a topological diagram of an adaptive IGBT active drive circuit;

FIG. 2 is a switch-on sequence diagram of an adaptive IGBT active drive circuit;

FIG. 3 is a diagram showing commutation path of an adaptive IGBT active drive circuit suitable for power electronic energy equipment in a turn-on phase 1;

FIG. 4 is a diagram showing commutation path of an adaptive IGBT active drive circuit suitable for power electronic energy equipment in a turn-on phase 2;

FIG. 5 is a diagram showing commutation path of an adaptive IGBT active drive circuit suitable for power electronic energy equipment in a turn-on phase 3;

FIG. 6 is a diagram showing commutation path of an adaptive IGBT active drive circuit suitable for power electronic energy equipment in a turn-on phase 4; and

FIG. 7 is a diagram showing commutation path of an adaptive IGBT active drive circuit suitable for power electronic energy equipment in a turn-on phase 5.

### DETAILED DESCRIPTION

An objective of the present disclosure is to provide an adaptive IGBT active drive circuit suitable for power electronic energy equipment, which can achieve current and voltage oscillation suppression in the turn-on process, and can adapt to the change of voltage and current level, and the adaptive response has better immediacy.

An adaptive IGBT active drive circuit suitable for power electronic energy equipment is provided. The active drive circuit is composed of the following parts:
(1) a gate drive circuit, where the gate drive circuit includes a totem pole unit, and multi-level resistance switching is achieved by using a totem pole parallel structure; the totem pole unit includes five totem poles T1 to T5 connected in parallel, a totem pole T1 is used to achieve switching of a resistor Rₒₙ₁ in a turn-on process, a totem pole T2 and a totem pole T3 are used to achieve switching of a resistor Rₒₙ₃ and a resistor Rₒₙ₃, a totem pole T4 is used to achieve switching of a resistor R_{off} in a turn-off process, and a totem pole T5 is used to achieve active clamping in late stage of turn-off to suppress gate crosstalk;
(2) a feedback circuit, where the feedback circuit includes a comparison unit and a logic unit; the comparison unit includes divided resistors Rᵤ₁, Rᵤ₂, R_{d1} and R_{d2}, sampling resistors Rᵢ₁ and Rᵢ₂, and a comparator; an IGBT is divided into an upper IGBT and a lower IGBT which are connected in series and are complementary transistors for each other; I_{ref-H} and I_{ref_L} are current comparison thresholds of the upper IGBT and the lower IGBT at time tₐ in a turn-on phase, respectively, and Vref-H and V_{ref_L} are voltage comparison thresholds of the upper IGBT and the lower IGBT at time t_{b} and time t_{c} in the turn-on phase, respectively; a collector emitter voltage V_{CE_H} of the upper IGBT and a collector emitter voltage V_{CE_L} of the lower IGBT are subjected to voltage division by the divided resistors Rᵤ₁, Rᵤ₂, R_{d1} and R_{d2}, and then are compared with the voltage comparison thresholds V_{ref-H} and V_{ref_L}, respectively, to output digital signals to participate in control of totem poles; internal currents of the upper IGBT and the lower IGBT, after passing through the sampling resistors Rᵢ₁ and Rᵢ₂, are compared with the current comparison threshold I_{ref-H} of the upper IGBT and the current comparison threshold I_{ref-L} of the lower IGBT to output digital signals to participate in the control of the totem poles; values of the voltage comparison thresholds V_{ref-H} and V_{ref_L} and the current comparison thresholds I_{ref-H} and I_{ref_L} are appropriate to provide judgment conditions for achieving self-adaptation for suppressing turn-on voltage oscillation under different voltage and current levels; and the logic unit is responsible for logically combine a pulse width modulation (PWM) signal with a signal output by the comparison unit to obtain a driving signal of the totem pole.

In an embodiment, the totem pole T1 is connected to Rₒₙ₁ and a diode D1 in sequence, and if the totem pole T1 is turned on, a branch including the Rₒₙ₁ and the diode D1 is switched on. The totem pole T2 is connected to Rₒₙ₂ and a diode D2 in sequence, and if the totem pole T2 is turned on, a branch including the Rₒₙ₂ and the diode D2 is switched on. The totem pole 13 is connected to Rₒₙ₃ and a diode D3 in sequence, and if the totem pole T3 is turned on, a branch including the Rₒₙ₃ and the diode D3 is switched on.

A control method for an adaptive IGBT active drive circuit suitable for power electronic energy equipment is provided, including the following steps:
Step (1), in phase 1, t∈[t₀, t₁]: in the phase, enabling a gate of the upper IGBT to start charging a gate capacitor C_{ge} under action of a driving power supply, such that a gate emitter voltage V_{GE} rises from a negative voltage to a threshold voltage Vₜₕ, and a collector emitter voltage V_{CE_H} and a collector current I_{C_H} of the upper IGBT are unchanged, where, in the phase, the upper IGBT is in an off state, and only upper transistors of the totem pole T4 and the totem pole T5 are turned on in the whole turn-on process, but due to a blocking effect of a diode D4 and a diode D5, no current passes through the upper transistors of the totem pole T4 and the totem pole T5;
Step (2), in phase 2, t∈[t₁, t₂]: in the phase, charging the gate of the upper IGBT continuously, to switch on the IGBT, where the gate emitter voltage V_{GE} of the upper IGBT rises from the threshold voltage Vₜₕ to a Miller plateau voltage Vₘᵢₗ, an inductor current gradually commutates from a freewheeling diode VT2 to the IGBT, and the collector current I_{C_H} of the upper IGBT starts to rise rapidly, namely:

$${I}_{C \_ H} = {g}_{m} ( {V}_{G E} - {V}_{t h} ) ;$$

in the equation, gₘ is a transconductance of the IGBT, V_{GE} is the gate emitter voltage, and Vₜₕ is the threshold voltage;
as excessive di/dt makes a reverse recovery current of the freewheeling diode VT2 increase rapidly, the collector current I_{C_H} of the upper IGBT produces a current spike, with an oscillation amplitude as follows:

$${I}_{r r} = \sqrt{\frac{{2 {Q}_{r r} d {i}_{C \_ H} / dt \vert}_{t = {t}_{2}}}{S + 1}} ;$$

in the equation, Oᵣᵣ is a reverse recovery charge, S is a softness factor, and di_{C_H}/dt is a collector current change rate;
in the equation, di_{C_H}/dt is as follows:

$$\frac{d {i}_{C \_ H}}{d t} = \frac{{g}_{m} ( {V}_{g \_ H} - {V}_{t h} ) - {I}_{C \_ H}}{{R}_{g} {C}_{i e s} + {L}_{e} {g}_{m}} ;$$

in the equation, V_{g_H} is a driving voltage, Lₑ is an emitter parasitic inductance, Cᵢₑₛ is an input capacitance, R_{g} is a gate resistance, which is sum of internal gate driving resistance Rᵢₙₜ of the IGBT and additional external gate driving resistance Rₑₓₜ;
a change of the collector current I_{C_H} of the upper IGBT is able to cause a slight decrease of the collector emitter voltage V_{CE_H} of the upper IGBT, with expression as follows:

$${V}_{CE \_ H} = {V}_{dc} - ( {L}_{c} + {L}_{e} ) {di}_{C \_ H} / dt ;$$

in the equation, L_{c} is a collector parasitic inductance, and V_{dc} is a DC terminal voltage.

Therefore, in t₀−tₐ phase, upper transistors of the totem poles T1 and T2 are turned on simultaneously, a resistor Rₒₙ₁ and a resistor Rₒₙ₂ are connected in parallel, such that a value of total resistance connected to the gate in series is smaller than a value of each of the resistor Rₒₙ₁ and the resistor Rₒₙ₃, thereby accelerating the rise speed, and reducing a driving loss; and driving resistance in the phase is as follows:

$${R}_{g 1} = \frac{{R}_{on 1} {R}_{on 2}}{{R}_{on 1} + {R}_{on 2}} + {R}_{int} ;$$

where Rᵢₙₜ is internal gate driving resistance of the IGBT;
at time tₐ, through a comparison threshold signal when a current I_{C_L} of a lower IGBT is close to 0, that is, prior to voltage and current oscillation, an upper transistor of the totem pole T2 is turned off, the diode D2 and the diode D3 are blocked, and the resistor Rₒₙ₂ is switched out, and the high resistor Rₒₙ₁ suppresses voltage and current oscillation of the upper IGBT; and driving resistance at the time is as follows:

$${R}_{g 2} = {R}_{on 1} + {R}_{int} ;$$

Step (3), in phase 3, the [t₂, t₃]: in the phase, due to influence of Miller effect, enabling input capacitance Cᵢₑₛ to be sum of gate collector capacitance C_{gc} and gate emitter capacitance C_{ge}, where the input capacitance Cᵢₑₛ is big enough to cause production of Miller plateau, and thus a gate current completely flows into a gate collector capacitor C_{gc}; the gate emitter voltage V_{GE} remains unchanged at the Miller plateau voltage Vₘᵢₗ, the collector emitter voltage V_{CE_H} of the upper IGBT drops at a relatively fast rate, and the collector current I_{C_H} of the upper IGBT rises to a peak value, and then drops to and remains at a stable turn-on current.

Therefore, at time t_{b}, through a comparison threshold signal when the collector emitter voltage V_{CE_L} of the lower IGBT is close to 0, that is, after the voltage and current oscillation, an upper transistor of the totem pole T3 is turned on, and a low driving resistor Rₒₙ₂ (the resistance value of the driving resistor Rₒₙ₃ at time to is lower than that at time t₂ and lower than that at time t₃) is switched in a loop to accelerate a voltage change rate of a Miller plateau area, so as to optimize a turn-on loss; and in addition, only upper transistors of the totem pole T4 and the totem pole T5 are turned on in the whole turn-on process, but due to a blocking effect of the diode D4 and the diode D5, no current passes through the upper transistors of the totem pole T4 and the totem pole T5; and driving resistance in the phase is as follows:

$${R}_{g 3} = \frac{{R}_{on 1} {R}_{on 3}}{{R}_{on 1} + {R}_{on 3}} + {R}_{int} ;$$

at time t_{c}, through a comparison threshold signal when the collector emitter voltage V_{CE_H} of the upper IGBT is close to 0, that is, prior to voltage oscillation of the complementary transistor, the upper transistor of the totem pole T3 is turned off, the diode D2 and the diode D3 are blocked, and Rₒₙ₃ is switched out, and the voltage oscillation of the complementary transistor is suppressed by the high resistor Rₒₙ₁; and driving resistance at the time is as follows:

$${R}_{g 4} = {R}_{on 1} + {R}_{int} ;$$

Step (4), in phase 4, t∈[t₃, t₄]: in the phase, due to disappearance of the Miller effect, enabling the gate emitter voltage V_{GE} continue to rise to a final value V_{Gon}, and enabling the collector emitter voltage V_{CE_H} of the upper IGBT to drop to a saturation on-state voltage drop, and then drop to zero and remain unchanged, where the collector emitter voltage V_{CE_L} of the lower IGBT is close to a DC terminal voltage V_{dc}, and voltage oscillation is generated under the influence of parasitic inductance, and the whole turn-on process is finished;
at time t_{d}, through starting a delay module for time delaying at the time t_{c}, namely, after the voltage oscillation of the complementary transistor, the upper transistor of the totem pole T2 is turned on, the resistor Rₒₙ₂ is switched in a loop; and a resistor obtained by connecting Rₒₙ₁ and Rₒₙ₂ in parallel accelerates the turn-on process, and driving resistance at the time is as follows:

$${R}_{g 5} = \frac{{R}_{on 1} {R}_{on 2}}{{R}_{on 1} + {R}_{on 2}} + {R}_{int} .$$

The present disclosure has following beneficial effects:
1. An adaptive IGBT active drive circuit suitable for power electronic energy equipment is constructed by using totem poles and other devices, which considers the performance and complexity of the system and does not need to change an original system structure too much.
2. Adaptive control is conducted through information of a transistor and its complementary transistor. Under such driving strategy, at time tₐ, through a comparison threshold signal when the I_{C_L} of the complementary transistor is close to 0, an upper transistor of T2 is turned off to suppress its own voltage and current oscillation. At time t_{b}, through a comparison threshold voltage when the V_{CE_L} of the lower transistor is close to 0, an upper transistor of T3 is turned on to accelerate the voltage change rate of the Miller plateau area, so as to optimize the turn-on loss. At time t_{c}, through a comparison threshold signal when its own V_{CE_H} is close to 0, an upper transistor of T3 is turned off to suppress voltage oscillation of the complementary transistor. That is, the active drive circuit provided by the present disclosure not only can effectively suppress the current and voltage oscillation in the turn-on process, but also is suitable for different voltage and current levels, and thus has better adaptive immediacy, higher reliability and expansibility.

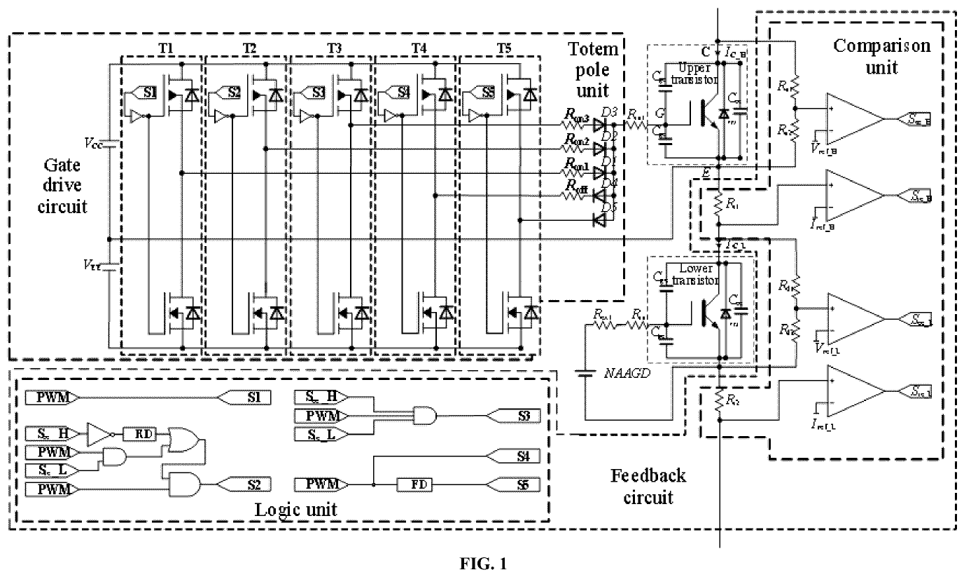

As shown in FIG. 1, an adaptive IGBT active drive circuit suitable for power electronic energy equipment is provided. The active drive circuit is composed of the following parts:
(1) A gate drive circuit. The gate drive circuit includes a totem pole unit, and multi-level resistance switching is achieved using a totem pole parallel structure. The totem pole unit includes five totem poles T1 to T5 connected in parallel. The totem pole T1 is used to achieve switching of a high resistor Rₒₙ₁ in a turn-on process. A totem pole T2 and a totem pole T3 are used to achieve switching of a low resistor Rₒₙ₂ and a low resistor Rₒₙ₃. A totem pole T4 is used to achieve switching of a low resistor R_{off} in a turn-off process. A totem pole T5 is used to achieve active clamping in late stage of turn-off to suppress gate crosstalk.
(2) Feedback circuit. The feedback circuit includes a comparison unit and a logic unit. The comparison unit includes divided resistors Rᵤ₁, Rᵤ₂, R_{d1} and R_{d2}, sampling resistors Rᵢ₁ and Rᵢ₂, and a comparator. The IGBT is divided into an upper IGBT and a lower IGBT which are connected in series and are complementary transistors for each other. I_{ref-H} and I_{ref_L} are current comparison thresholds of an upper IGBT and a lower IGBT at time tₐ in a turn-on phase, respectively, and V_{ref-H} and V_{ref_L} are voltage comparison thresholds of the upper IGBT and the lower IGBT at time to and time t_{c} in the turn-on phase, respectively. A collector-emitter voltage V_{CE_H} of the upper IGBT and a collector-emitter voltage V_{CE_L} of the lower IGBT are subjected to voltage division by the divided resistors Rᵤ₁, Rᵤ₂, R_{d1} and R_{d2}, and then are compared with the voltage comparison thresholds V_{ref-H} and V_{ref_L}, respectively, to output digital signals to participate in control of totem poles. Internal currents of the upper IGBT and the lower IGBT, after passing through the sampling resistors Rᵢ₁ and Rᵢ₂, are compared with the current comparison threshold I_{ref-H} of the upper IGBT and the current comparison threshold I_{ref-L} of the lower IGBT to output digital signals to participate in the control of the totem poles. Voltage and current comparison thresholds need to be set as relatively small values to provide judgment conditions for achieving self-adaptation for suppressing turn-on voltage oscillation under different voltage and current levels. The logic unit is responsible for logically combining a PWM signal with a signal output by the comparison unit to obtain a driving signal of the totem pole.

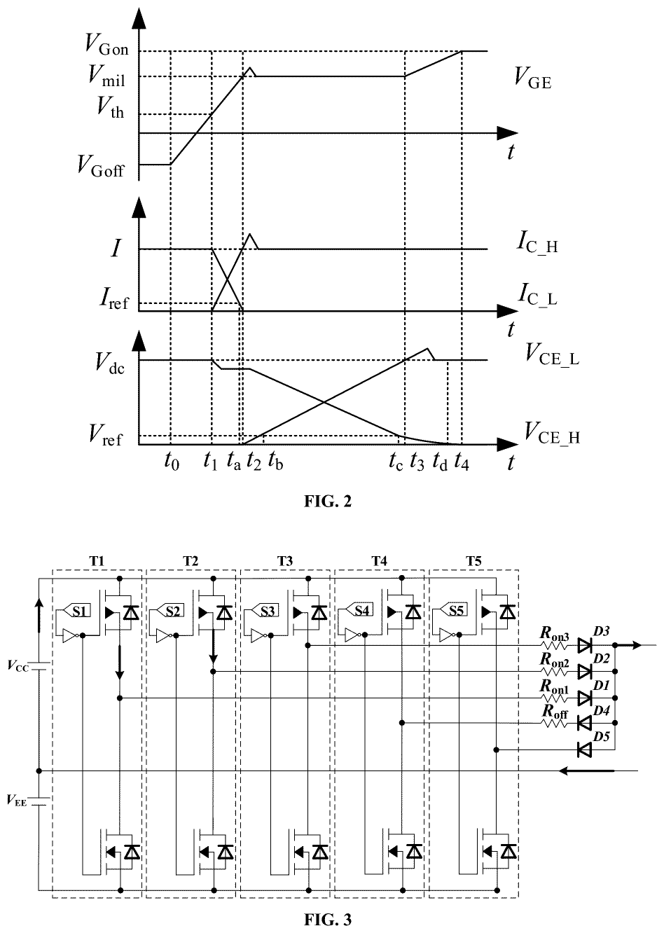

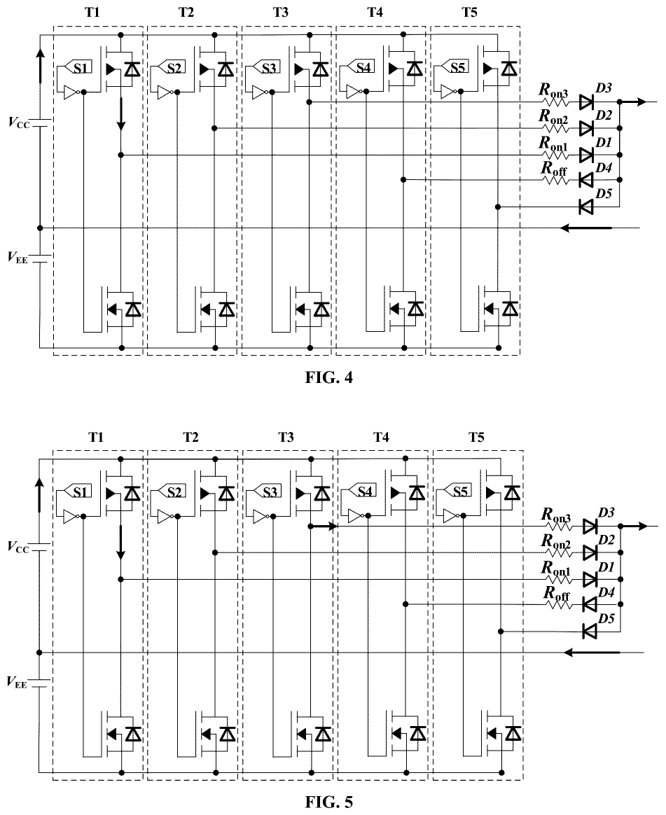

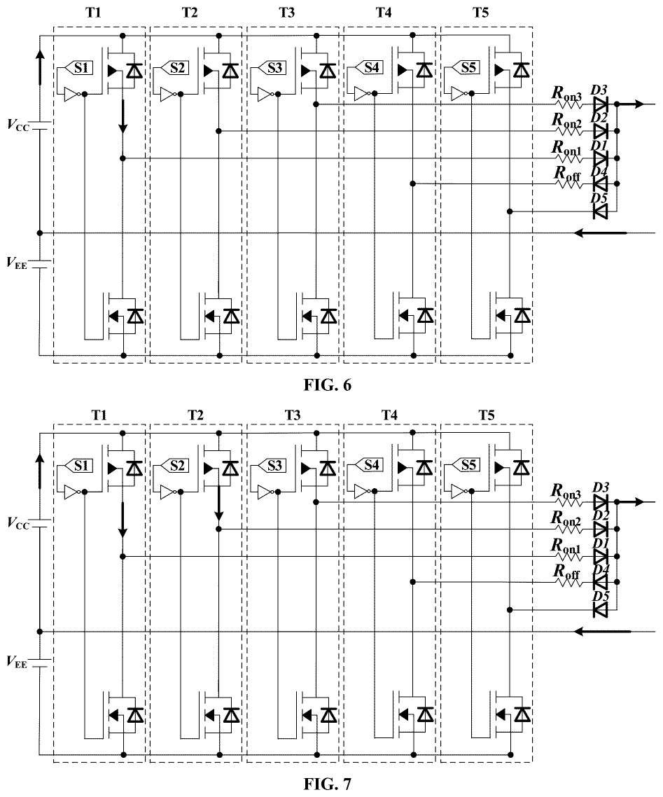

FIG. 2 is a switch-on process of an adaptive IGBT active drive circuit. As can be seen from FIG. 2, in one cycle, i.e., during the period from t₀ to t₄, the turn-on process can be divided into five phases, the five turn-on phases are specifically as shown in FIG. 3 to FIG. 7. A control method for an adaptive IGBT active drive circuit is further provided, including the following steps:
(1) In a t₀−tₐ phase, an upper transistor of a totem pole T3 is turned off, and a diode D3 is blocked. Upper transistors of a totem pole T1 and a totem pole T2 are turned on, V_{CC} charges the gate of the upper IGBT in the bridge arm in FIG. 1 (i.e., the gate of the transistor labeled “Upper Transistor” in FIG. 1) through a low resistor obtained by connecting a resistor Rₒₙ₁ and a resistor Rₒₙ₂ in parallel to achieve shorter turn-on delay time. In addition, only upper transistors of a totem pole T4 and a totem pole T5 are turned on in the whole turn-on process, but due to a blocking effect of a diode D4 and a diode D5, no current passes through the upper transistors of the totem pole T4 and the totem pole T5, as shown in FIG. 3.
(2) In a tₐ−t_{b} phase, through a comparison threshold signal when a current I_{C_L} of a lower IGBT is close to 0, that is, prior to voltage and current oscillation, the upper transistor of the totem pole T2 is turned off, a diode D2 and a diode D3 are blocked, and the resistor Rₒₙ₂ is switched out, and the high resistor Rom suppresses the voltage and current oscillation, as shown in FIG. 4. (3) In a t_{b}−t_{c} phase, through a comparison threshold signal when a collector-emitter voltage V_{CE_L} of the lower IGBT is close to 0, that is, after the current oscillation of the upper IGBT, an upper transistor of a totem pole T3 is turned on, and a low driving resistor Rₒₙ₂ is switched in a loop to accelerate a voltage change rate of a Miller plateau area, so as to optimize a turn-on loss. In addition, only upper transistors of the totem pole T4 and the totem pole T5 are turned on in the whole turn-on process, but due to a blocking effect of the diode D4 and the diode D5, no current passes through the upper transistors of the totem pole T4 and the totem pole T5, as shown in FIG. 5.
(4) In a t_{c}−t_{d} phase, through a comparison threshold signal when a collector-emitter voltage V_{CE_H} of the upper IGBT is close to 0, that is, prior to voltage oscillation of the lower IGBT, the upper transistor of the totem pole T3 is turned off, a diode D2 and a diode D3 are blocked, and Rₒₙ₃ is switched out, and the voltage oscillation of the complementary transistor is suppressed by the high resistor Ron, as shown in FIG. 6.
(5) In a t_{d}−t₄ phase, through starting a delay module for time delay at the time t_{c}, namely, after voltage oscillation of the lower IGBT, the upper transistor of the totem pole T2 is turned on, the resistor Rₒₙ₂ is switched in the loop. A low resistor connected to Rₒₙ₁ and Rₒₙ₂ in parallel accelerates the turn-on process, as shown in FIG. 7.

The feedback circuit according to the present disclosure is a pair of complementary transistors, and for the upper transistor, the lower transistor is a complementary transistor thereof. For the lower transistor, the upper transistor is a complementary transistor thereof. The upper transistor and the lower transistor are complementary transistors for each other, and the voltage and current are sampled to provide adaptive judgment conditions for the gate drive circuit. At time tₐ in the turn-on phase, through a current comparison threshold of the complementary transistor, the driving resistance is increased to reduce the current oscillation. At time to in the turn-on phase, through a voltage comparison threshold of the complementary transistor, the driving resistance is reduced to accelerate the Miller plateau area and optimize the turn-on loss of the Miller plateau area. At time t_{c} in the turn-on phase, through a voltage comparison threshold of its own transistor, the driving resistance is increased to reduce the voltage oscillation of the complementary transistor.

The present disclosure considers the performance and complexity of the system, and has good self-adaptation and immediacy at the same time, so as to achieve the current and voltage oscillation suppression under different current and voltage levels. As the Miller plateau voltage Vₘᵢₗ will reduce with the decrease of current level, the duration of the Miller plateau area can be reduced by increasing a driving current of the Miller plateau area. When the voltage level decreases, the duration of the Miller plateau area will also be reduced. However, the voltage circuit sampling of the upper and lower transistors is mutually utilized, such that the time tₐ can always be before a current oscillation amplitude, the time t_{b} can always be after the current oscillation amplitude, and the time t_{c} can always be before a voltage oscillation amplitude, thereby achieving the real-time adaptation of the voltage oscillation suppression effect to the voltage and current level during the turn-on process.

The average driving resistance of the adaptive IGBT active drive circuit in the turn-on phase is lower, indicating that the loss can be optimized. Through the mutual utilization of voltage circuit sampling of the upper and lower transistors, the time tₐ can always be before the current oscillation amplitude, the time t_{b} can always be after the current oscillation amplitude, and the time t_{c} can always be before a voltage oscillation amplitude, thereby achieving the real-time adaptation of the voltage oscillation suppression effect to the voltage and current class during the turn-on process.

The matters not mentioned in the present disclosure are known in the art. The aforementioned embodiments are merely used for illustrating the technical thoughts and features of the present disclosure, for enabling those skilled in the art to understand the contents of the present disclosure and implement the contents accordingly, and the scope of protection of the present disclosure cannot be limited hereto. Any equivalent changes or modifications made according to the technical solutions of the present disclosure shall fall within the scope of protection of the present disclosure.

1. An adaptive insulated-gate bipolar transistor (IGBT) active drive circuit suitable for power electronic energy equipment, the adaptive IGBT active drive circuit comprising:
a gate drive circuit comprising a totem pole unit, and multi-level resistance switching is achieved by using a totem pole parallel structure; the totem pole unit comprises five totem poles T1 to T5 connected in parallel, a totem pole T1 is used to achieve switching of a resistor Rom with a first resistance value in a turn-on process, a totem pole T2 and a totem pole T3 are used to achieve switching of a resistor Rₒₙ₂ with a second resistance value and a resistor Rₒₙ₃ with a third resistance value, a totem pole T4 is used to achieve switching of a resistor R_{off} with a fourth resistance value in a turn-off process, and a totem pole T5 is used to achieve active clamping in late stage of turn-off to suppress gate crosstalk; wherein the first resistance value is bigger than any of the second resistance value, the third resistance value and the fourth resistance value; and
a feedback circuit, wherein the feedback circuit is composed of a comparison unit and a logic unit; the comparison unit comprises divided resistors Rᵤ₁, Rᵤ₂, R_{d1} and R_{d2}, sampling resistors Rᵢ₁ and Rᵢ₂, and a comparator; an IGBT is divided into an upper IGBT and a lower IGBT which are connected in series and are complementary transistors for each other; I_{ref-H} and I_{ref_L} are current comparison thresholds of the upper IGBT and the lower IGBT at time tₐ in a turn-on phase, respectively, and V_{ref-H} and V_{ref_L} are voltage comparison thresholds of the upper IGBT and the lower IGBT at time t_{b} and time t_{c} in the turn-on phase, respectively;
wherein a collector-emitter voltage V_{CE_H} of the upper IGBT and a collector-emitter voltage V_{CE_L} of the lower IGBT are subjected to voltage division by the divided resistors Rᵤ₁, Rᵤ₂, R_{d1} and R_{d2}, and then are compared with the voltage comparison thresholds V_{ref-H} and V_{ref_L} respectively, to output digital signals to participate in control of totem poles; internal currents of the upper IGBT and the lower IGBT, after passing through the sampling resistors Rᵢ₁ and Rᵢ₂, are compared with a current comparison threshold I_{ref-H} of the upper IGBT and a current comparison threshold I_{ref-L} of the lower IGBT to output digital signals to participate in the control of the totem poles; values of the voltage comparison thresholds V_{ref-H} and V_{ref_L} and the current comparison thresholds I_{ref-H} and I_{ref_L} are appropriate to provide judgment conditions for achieving self-adaptation for suppressing turn-on voltage oscillation under different voltage and current levels; and the logic unit is responsible for logically combine a pulse width modulation (PWM) signal with a signal output by the comparison unit to obtain a driving signal of the totem pole.

2. The adaptive IGBT active drive circuit according to claim 1, wherein the totem pole T1 is connected to Rₒₙ₁ and a diode D1 in sequence, and if the totem pole T1 is turned on, a branch composed of the Rom and the diode D1 is switched on; the totem pole T2 is connected to Rₒₙ₂ and a diode D2 in sequence, and if the totem pole T2 is turned on, a branch composed of the Rₒₙ₂ and the diode D2 is switched on; and the totem pole T3 is connected to Rₒₙ₃ and a diode D3 in sequence, and if the totem pole T3 is turned on, a branch composed of the Rₒₙ₃ and the diode D3 is switched on.

3. A method for an adaptive IGBT active drive circuit suitable for power electronic energy equipment comprising a gate drive circuit comprising a totem pole unit, and multi-level resistance switching is achieved by using a totem pole parallel structure; the totem pole unit comprises five totem poles T1 to T5 connected in parallel, a totem pole T1 is used to achieve switching of a resistor Rₒₙ₁ with a first resistance value in a turn-on process, a totem pole T2 and a totem pole T3 are used to achieve switching of a resistor Rₒₙ₂ with a second resistance value and a resistor Rₒₙ₃ with a third resistance value, a totem pole T4 is used to achieve switching of a resistor R_{off} with a fourth resistance value in a turn-off process, and a totem pole T5 is used to achieve active clamping in late stage of turn-off to suppress gate crosstalk; wherein the first resistance value is bigger than any of the second resistance value, the third resistance value and the fourth resistance value; a feedback circuit, wherein the feedback circuit is composed of a comparison unit and a logic unit; the comparison unit comprises divided resistors Rᵤ₁, Rᵤ₂, R_{d1} and R_{d2}, sampling resistors Rᵢ₁ and Rᵢ₂, and a comparator; an IGBT is divided into an upper IGBT and a lower IGBT which are connected in series and are complementary transistors for each other; I_{ref-H} and I_{ref_L} are current comparison thresholds of the upper IGBT and the lower IGBT at time tₐ in a turn-on phase, respectively, and V_{ref-H} and V_{ref_L} are voltage comparison thresholds of the upper IGBT and the lower IGBT at time t_{b} and time t_{c} in the turn-on phase, respectively; a collector-emitter voltage V_{CE_H} of the upper IGBT and a collector-emitter voltage V_{CE_L} of the lower IGBT are subjected to voltage division by the divided resistors Rᵤ₁, Rᵤ₂, R_{d1} and R_{d2}, and then are compared with the voltage comparison thresholds V_{ref-H} and V_{ref_L} respectively, to output digital signals to participate in control of totem poles; internal currents of the upper IGBT and the lower IGBT, after passing through the sampling resistors Rᵢ₁ and Rᵢ₂, are compared with a current comparison threshold I_{ref-H} of the upper IGBT and a current comparison threshold I_{ref-L} of the lower IGBT to output digital signals to participate in the control of the totem poles; values of the voltage comparison thresholds V_{ref-H} and V_{ref_L} and the current comparison thresholds I_{ref-H} and I_{ref_L} are appropriate to provide judgment conditions for achieving self-adaptation for suppressing turn-on voltage oscillation under different voltage and current levels; and the logic unit is responsible for logically combine a pulse width modulation (PWM) signal with a signal output by the comparison unit to obtain a driving signal of the totem pole, the method comprising:
in phase 1, t∈[t₀, t₁]: in the phase, enabling a gate of the upper IGBT to start charging a gate capacitor C_{ge} under action of a driving power supply, such that a gate-emitter voltage V_{GE} rises from a negative voltage to a threshold voltage Vₜₕ, and a collector-emitter voltage V_{CE_H} and a collector current I_{C_H} of the upper IGBT are unchanged, wherein, in the phase, the upper IGBT is in an off state, and only upper transistors of the totem pole T4 and the totem pole T5 are turned on in the whole turn-on process, but due to a blocking effect of a diode D4 and a diode D5, no current passes through the upper transistors of the totem pole T4 and the totem pole T5; and
in phase 2, t∈[t₁, t₂]: in the phase, charging the gate of the upper transistors of the IGBT continuously, to switch on the IGBT, wherein the gate-emitter voltage V_{GE} of the upper IGBT rises from the threshold voltage Vₜₕ to a Miller plateau voltage Vₘᵢₗ, an inductor current gradually commutates from a freewheeling diode VT2 to the IGBT, and a rising speed of the collector current I_{C_H} of the upper IGBT starts to increase, namely:
$${I}_{C\_H} = {g}_{m} ( {V}_{GE} - {V}_{th} ) ;$$
wherein gₘ is a transconductance of the IGBT, V_{GE} is the gate-emitter voltage, and Vₜₕ is the threshold voltage;
a reverse recovery current of the freewheeling diode VT2 increases along with increment of di/dt, the collector current I_{C_H} of the upper IGBT produces a current spike, with an oscillation amplitude as follows:
$${I}_{rr} = \sqrt{\frac{2 {Q}_{rr} {di}_{C \_ H} / dt {\vert}_{t = {t}_{2}}}{S + 1}} ;$$
wherein Qᵣᵣ is a reverse recovery charge, S is a softness factor, and di_{C_H}/dt is a collector current change rate;
in above equation, di_{C_H}/dt is as follows:
$$\frac{{di}_{C \_ H}}{dt} = \frac{{g}_{m} ( {V}_{g \_ H} - {V}_{th} ) - {I}_{C \_ H}}{{R}_{g} {C}_{ies} + {L}_{e} {g}_{m}} ;$$
wherein V_{g_H} is a driving voltage, Lₑ is an emitter parasitic inductance, Cᵢₑₛ is an input capacitance, R_{g} is a gate resistance, which is sum of internal gate driving resistance Rᵢₙₜ of the IGBT and additional external gate driving resistance Rₑₓₜ;
a change of the collector current I_{C_H} of the upper IGBT is able to cause a decrease of the collector-emitter voltage V_{CE_H} of the upper IGBT, with expression as follows:
$${V}_{CE \_ H} = {V}_{dc} - ( {L}_{c} + {L}_{e} ) {di}_{C \_ H} / dt ;$$
wherein L_{c} is a collector parasitic inductance, and V_{dc} is a DC terminal voltage;
therefore, in t₀−tₐ phase, upper transistors of the totem poles T1 and T2 are turned on simultaneously, a resistor Rₒₙ₁ and a resistor Rₒₙ₂ are connected in parallel, such that a value of total resistance connected to the gate in series is smaller than a resistance value of each of the resistor Rₒₙ₁ and the resistor Rₒₙ₃, thereby accelerating a rise speed, and reducing a driving loss; and driving resistance in the phase is as follows:
$${R}_{g 1} = \frac{{R}_{on 1} {R}_{on 2}}{{R}_{on 1} + {R}_{on 2}} + {R}_{int} ;$$
wherein Rᵢₙₜ is internal gate driving resistance of the IGBT;
at time tₐ, through a comparison threshold signal when a current I_{C_L} of a lower IGBT is close to 0, that is, prior to voltage and current oscillation, an upper transistor of the totem pole T2 is turned off, a diode D2 and a diode D3 are blocked, and the resistor Rₒₙ₂ is switched out, and the resistor Rom with the first resistance value suppresses voltage and current oscillation of the upper IGBT in a bridge arm; and driving resistance at the time is as follows:
$${R}_{g 2} = {R}_{on 1} + {R}_{int} ;$$
in phase 3, t∈[t₂, t₃]: in the phase, due to influence of Miller effect, enabling input capacitance Cᵢₑₛ to be sum of gate-collector capacitance C_{gc} and gate-emitter capacitance C_{ge}, wherein the input capacitance Cᵢₑₛ is big enough to cause production of Miller plateau, and thus a gate current completely flows into a gate-collector capacitor C_{gc}; the gate-emitter voltage V_{GE} remains unchanged at the Miller plateau voltage Vₘᵢₗ, a rate of the collector-emitter voltage V_{CE_H} drop of the upper IGBT increases, and the collector current I_{C_H} of the upper IGBT rises to a peak value, and then drops to and remains at a turn-on current;
therefore, at time t_{b}, through a comparison threshold signal when the collector-emitter voltage V_{CE_L} of the lower IGBT is close to 0, that is, after the voltage and current oscillation, an upper transistor of the totem pole T3 is turned on, and a driving resistor Rₒₙ₃ is switched in a loop to accelerate a voltage change rate of a Miller plateau area, so as to optimize a turn-on loss, wherein resistance value of the driving resistor Rₒₙ₃ at time t_{b} is lower than that at time t₂ and lower than that at time t₃; and in addition, only upper transistors of the totem pole T4 and the totem pole T5 are turned on in the whole turn-on process, but due to a blocking effect of the diode D4 and the diode D5, no current passes through the upper transistors of the totem pole T4 and the totem pole T5; and driving resistance in the phase is as follows:
$${R}_{g 3} = \frac{{R}_{on 1} {R}_{on 3}}{{R}_{on 1} + {R}_{on 3}} + {R}_{int} ;$$
at time t_{c}, through a comparison threshold signal when the collector-emitter voltage V_{CE_H} of the upper IGBT is close to 0, that is, prior to voltage oscillation of the complementary transistor, the upper transistor of the totem pole T3 is turned off, the diode D2 and the diode D3 are blocked, and Rₒₙ₃ is switched out, and the voltage oscillation of the complementary transistor is suppressed by the resistor Rₒₙ₁ with the first resistance value; and driving resistance at the time is as follows:
$${R}_{g 4} = {R}_{on 1} + {R}_{int} ;$$
in phase 4, t∈[t₃, t₄]: in the phase, due to disappearance of the Miller effect, enabling the gate emitter voltage V_{GE} continue to rise to a final value V_{Gon}, and enabling the collector-emitter voltage V_{CE_H} of the upper IGBT to drop to a saturation on-state voltage drop, and then drop to zero and remain unchanged, wherein the collector-emitter voltage V_{CE_L} of the lower IGBT is close to a DC terminal voltage V_{dc}, and voltage oscillation is generated under the influence of parasitic inductance, and the whole turn-on process is finished;
at time t_{d}, through starting a delay module for time delaying at the time t_{c}, namely, after the voltage oscillation of the complementary transistor, the upper transistor of the totem pole T2 is turned on, the resistor Rₒₙ₂ is switched in a loop; and a resistor with a fifth resistance value obtained by connecting Rₒₙ₁ and Rₒₙ₂ in parallel accelerates the turn-on process, and driving resistance at the time is as follows:
$${R}_{g 5} = \frac{{R}_{on 1} {R}_{on 2}}{{R}_{on 1} + {R}_{on 2}} + {R}_{int} .$$

4. The method for the adaptive IGBT active drive circuit suitable for power electronic energy equipment according to claim 3, wherein the totem pole T1 is connected to Rₒₙ₁ and a diode D1 in sequence, and if the totem pole T1 is turned on, a branch composed of the Rₒₙ₁ and the diode D1 is switched on; the totem pole T2 is connected to Rₒₙ₂ and a diode D2 in sequence, and if the totem pole T2 is turned on, a branch composed of the Rₒₙ₂ and the diode D2 is switched on; and the totem pole T3 is connected to Rₒₙ₃ and a diode D3 in sequence, and if the totem pole T3 is turned on, a branch composed of the Rₒₙ₃ and the diode D3 is switched on.
